(19) United States
(12) Patent Application Publication
(10) Pub. No.: US 2007/0128775 A1
(43) Pub. Date: Jun. 7, 2007

(54) Method of manufacturing a semiconductor device having a tungsten carbon nitride layer

(75) Inventors: Taek-Soo Jeon, Yongin-si (KR); Hag-ju Cho, Yongin-si (KR); Hye-Lan Lee, Hwaseong-si (KR); Yu-Gyun Shin, Seongnam-si (KR); Sang-Bom Kang, Seoul (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/607,600

(22) Filed: Dec. 1, 2006

(30) Foreign Application Priority Data
Dec. 2, 2005 (KR) 10-2005-0116754

(51) Int. Cl. H01L 21/84

(52) U.S. Cl. 438/149

(57) ABSTRACT

A method of manufacturing a gate electrode of a MOS transistor including a tungsten carbon nitride layer is disclosed. After a high dielectric layer is formed on a substrate, a source gas including tungsten amine derivative flows onto the high dielectric layer. A tungsten carbon nitride layer is formed on the high dielectric layer by decomposing the source gas. Thereafter, a gate electrode is formed by patterning the tungsten carbon nitride layer. According to the present invention, a gate electrode having a work function of over 4.9 eV is formed.

### CROSS-REFERENCE TO RELATED APPLICATIONS

This application claims priority under 35 U.S.C. § 119 to Korean Patent Application No. 2005-116754 filed on Dec. 2, 2005, the contents of which are herein incorporated by reference in their entirety.

### BACKGROUND OF THE INVENTION

1. Field of the Invention

Example embodiments of the present invention relate to methods of manufacturing a semiconductor device including a tungsten carbon nitride layer and to semiconductor devices incorporating such layers. More particularly, example embodiments of the present invention relate to methods of manufacturing a semiconductor device including a tungsten carbon nitride layer that has a work function higher than or equal to about 4.9 eV

2. Description of the Related Art

In a semiconductor device, a metal oxide semiconductor (MOS) transistor is considered to be one of the most important unit devices. The MOS transistor typically includes a gate dielectric layer, a gate electrode and a source/drain region. The source/drain region is formed at an upper portion of a substrate adjacent to the gate electrode. In general, many semiconductor devices include a complementary metal oxide semiconductor (CMOS) transistor having an N-channel metal oxide semiconductor (NMOS) transistor and a P-channel metal oxide semiconductor (PMOS) transistor.

In the process of manufacturing the CMOS transistor, a silicon oxide layer formed by a thermal oxidation process is widely used as the gate dielectric layer. The gate electrodes in the NMOS transistor and the PMOS transistor are formed using the same conductive material to simplify a manufacturing process. The gate electrodes are, for example, formed using a polysilicon layer doped with N-type impurities such as phosphorus, arsenic, etc.

Because of a growing demand for semiconductor devices having a high operating speed and a low power consumption, efforts have been made to reduce a thickness of the gate dielectric layer. When the thickness of the gate dielectric layer is reduced below a critical thickness, however, a leakage current is generated from the gate dielectric layer which can deteriorate the electrical characteristics of the semiconductor device. A thickness of the silicon oxide layer, which is widely used as the gate dielectric layer in the semiconductor device, has already reached the critical thickness and therefore cannot be further reduced. Accordingly, methods of using the silicon oxide layer as the gate dielectric layer have some technical problems. Recently, a semiconductor device having a dielectric layer with a high dielectric constant as the gate dielectric layer instead of the silicon oxide layer has been developed. The term “a high dielectric constant” is used herein to describe a dielectric constant that is higher than about 3.9, which is a dielectric constant of silicon oxide (SiO₂). Examples of materials having such a high dielectric constant include tantalum oxide (Ta₂O₅), titanium oxide (TiO₂), hafnium oxide (HfO₂), etc. A dielectric layer having such a high dielectric constant has a thin equivalent oxide thickness (EOT) so that such a dielectric layer, even if it has a thickness larger than that of the silicon oxide layer, may still have enhanced electrical characteristics.

When the gate dielectric layer includes a dielectric material having the high dielectric constant and the gate electrode includes polysilicon doped with N-type or P-type impurities, a Fermi-level pinning phenomenon has been found to occur, and thus an absolute value of a threshold voltage in a transistor having this structure increases. Particularly, the absolute value of the threshold voltage excessively increases in the PMOS transistor. Thus, when the PMOS transistor includes the dielectric layer having the high dielectric constant, forming the gate electrode using polysilicon doped with P-type impurities is disadvantageous.

Also, when a capacitor includes an electrode having doped polysilicon and the high dielectric layer formed on the electrode, it has been found that doped polysilicon of the electrode reacts with the high dielectric layer so that a parasitic silicon oxide layer is generated between the electrode and the high dielectric layer. The parasitic silicon oxide layer has a relatively low permittivity and thereby reduces the capacitance of the capacitor.

To solve the above-mentioned problems, a novel conductive material has been developed, which may avoid the Fermi-level pinning and/or the generation of the parasitic silicon oxide layer even though the conductive material makes contact with the dielectric layer having the high dielectric constant. However, efforts to utilize the novel conductive material have presented some difficulties in relation to semiconductor manufacturing processes such as a deposition process and/or an etching process with high efficiency and low cost.

These and other limitations of and problems with the prior art techniques are addressed in whole, or at least in part, by the methods of this invention.

### SUMMARY OF THE INVENTION

Example embodiments of the present invention provide methods of manufacturing a gate structure including a gate electrode having a work function higher than or equal to about 4.9 eV and having good reaction resistance to a dielectric layer with a high dielectric constant.

Example embodiments of the present invention also provide methods of manufacturing a dual gate electrode including the above-mentioned gate electrode.

Example embodiments of the present invention further provide methods of manufacturing a capacitor having a good leakage current characteristic.

According to one aspect of the present invention, there is provided a method of manufacturing a gate electrode structure. In the method of manufacturing the gate electrode structure, a dielectric layer having a high dielectric constant is formed on a substrate. A source gas including a tungsten amine derivative is provided and contacted with the dielectric layer. A tungsten carbon nitride layer is then formed on the dielectric layer by decomposing the source gas. Thereafter, a gate electrode is formed on the dielectric layer by patterning the tungsten carbon nitride layer.

In a specific exemplary embodiment of the present invention, the source gas may include bis(tert-butylimido)bis(dimetylamido)tungsten.

According to another aspect of the present invention, there is provided a method of manufacturing a dual gate electrode. In the method of manufacturing the dual gate electrode, a dielectric layer having a high dielectric constant is formed on a substrate including an NMOS transistor region and a PMOS transistor region. A source gas including a tungsten amine derivative is provided and contacted with the dielectric layer. A tungsten carbon nitride layer having a first work function is formed on the high dielectric layer by decomposing the source gas, and this tungsten carbon nitride layer serves as a gate electrode of a PMOS gate electrode. A preliminary tungsten carbon nitride layer pattern is formed by partially etching the tungsten carbon nitride layer positioned in the NMOS transistor region. A conductive layer having a second work function is formed on the preliminary tungsten carbon nitride layer pattern and the high dielectric layer pattern, and this conductive layer serves as an NMOS gate electrode. A first gate electrode is formed on the dielectric layer of the PMOS transistor region by patterning the conductive layer and the tungsten carbon nitride layer, and the first gate electrode includes a tungsten carbon nitride layer pattern and a conductive layer pattern. A second gate electrode is formed on the dielectric layer of the NMOS transistor region by patterning the conductive layer, and the second electrode also includes a conductive layer pattern.

According to still another aspect of the present invention, there is provided a method of manufacturing a capacitor. In the method of manufacturing the capacitor, a source gas including tungsten amine derivative is provided and contacted with the substrate. A first electrode layer including a tungsten carbon nitride layer is formed by decomposing the source gas. A metal oxide layer including a dielectric material with a high dielectric constant is formed on the first electrode layer. Then, a second electrode layer is formed on the metal oxide layer.

According to a preferred embodiment of the present invention, a tungsten carbon nitride layer has a work function of about 4.9 eV to 5.1 eV. The tungsten carbon nitride layer has good reaction resistance to a dielectric layer having a high dielectric constant. Hence, as described above, a semiconductor device having high performance may be manufactured by applying the tungsten carbon nitride layer to a gate electrode and/or to a capacitor electrode.

### BRIEF DESCRIPTION OF THE DRAWINGS

The above and other features and advantages of the present invention will become more apparent by describing detailed example embodiments thereof with reference to the accompanying drawings, in which:

FIG. 1 is a schematic cross-sectional view illustrating a gate structure in accordance with an example embodiment of the present invention;

FIGS. 2 to 5 are cross-sectional views illustrating process steps in a method of forming a gate structure as shown in FIG. 1;

FIGS. 6 to 10 are schematic cross-sectional views illustrating a method of manufacturing a dual gate of a semiconductor device in accordance with an example embodiment of the present invention;

FIGS. 11 and 12 are schematic cross-sectional views illustrating a method of manufacturing a capacitor in accordance with an example embodiment of the present invention;

FIG. 13 is a graph illustrating characteristics of x-ray diffraction patterns in a tungsten carbon nitride layer prepared according to the present invention;

FIG. 14 is a graph illustrating a capacitance-voltage (C-V) characteristic of a MOS capacitor having a tungsten carbon nitride layer according to the present invention and various electrode materials as a gate electrode; and

FIG. 15 is a graph illustrating how a flat-band voltage and a work function of a tungsten carbon nitride layer vary according to a thickness of a hafnium silicon nitride layer.

### DESCRIPTION OF THE EMBODIMENTS

The present invention is described more fully hereinafter with reference to the accompanying drawings, in which example embodiments of the present invention are shown. The present invention may, however, be embodied in many different forms and should not be construed as limited to the example embodiments set forth herein. Rather, these embodiments are provided so that this disclosure will be thorough and complete, and will fully convey the scope of the present invention to those skilled in the art. In the drawings, it will be understood that the sizes and relative sizes of layers and regions may be exaggerated for clarity.

It will also be understood that when an element or layer is referred to as being “on,” “connected to” or “coupled to” another element or layer, it can be directly on, connected or coupled to the other element or layer or, alternatively, intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be further understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section as discussed below could instead be termed a second element, component, region, layer or section without departing from the teachings of the present invention.

Spatially relative terms, such as “beneath,” “below,” “lower,” “above,” “upper” and the like, may be used herein for ease of description to describe one element or feature's spatial relationship to another element(s) or feature(s) as illustrated in the figures. It will be understood, however, that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein should be interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-sectional illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a sharp binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which the present invention pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

### Embodiment 1

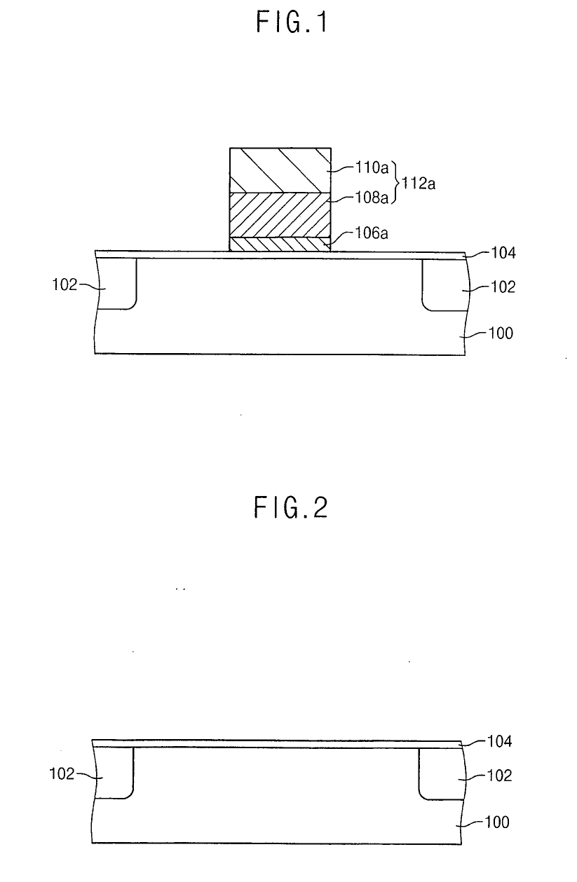

FIG. 1 is a schematic cross-sectional view illustrating a gate structure in accordance with a first example embodiment of the present invention. The first example embodiment of the present invention relates to the gate structure that may be applied to a PMOS transistor,

Referring to FIG. 1, an isolation layer 102 is formed at an upper portion of a substrate 100 to define an active region. A doping region (not shown) is formed below the active region of the substrate 100 to be provided as a channel region of a transistor. The doping region may be doped with N-type impurities such as phosphorus, arsenic, etc.

A dielectric layer 104 having a high dielectric constant as defined herein is formed on the substrate 100. The dielectric layer 104 is provided as a gate oxide layer. The dielectric layer 104 may include a metal oxide. For example, the dielectric layer 104 includes tantalum oxide (Ta₂O₅), titanium oxide (TiO₂), hafnium oxide (HfO₂), zirconium oxide (ZrO₂), hafnium silicon oxide (HfSiₓO_{y}), zirconium silicon oxide (ZrSiₓO_{y}), hafnium silicon oxynitride (HfSiₓO_{y}N_{z}), zirconium silicon oxynitride (ZrSiₓO_{y}N_{z}), aluminum oxide (Al₂O₃), aluminum oxynitride (AlₓO_{y}N_{z}), hafnium aluminum oxide (HfAlₓO_{y}), yttrium oxide (Y₂O₃), niobium oxide (Nb₂O₅), cerium oxide (CeO₂), indium oxide (InO₃), lanthanum oxide (LaO₂), iridium oxide (IrO₂), barium strontium titanium oxide ((Ba,Sr)TiO₃, also known as BST), lead zirconium titanium oxide (Pb(Zr,Ti)O₃, also known as PZT), strontium titanium oxide (SrTiO₃), lead titanium oxide (PbTiO₃), strontium ruthenium oxide (SrRuO₃), calcium ruthenium oxide (CaRuO₃), lead lanthanum zirconium titanium oxide ((Pb,La)(Zr,Ti)O₃), strontium calcium ruthenium oxide ((Sr,Ca)RuO₃), etc. In the preceding list, x, y and z are integers. These materials may be used alone or in a combination thereof. In addition, the dielectric layer 104 may have a laminated structure including multiple films with the above-mentioned materials.

A tungsten carbon nitride pattern 106a is formed on the high dielectric layer 104. The tungsten carbon nitride pattern 106a is formed by thermally decomposing a suitable source gas. In one invention embodiment, the source gas includes W(NR₁R₂)₂(NR₃)₂. In the preceding formula, R₁, R₂ and R₃ are selected from the group consisting of hydrogen atoms and C₁-C₆ alkyl groups, and R₁, R₂ and R₃ may be the same as or different from one another. The tungsten carbon nitride pattern 106a may include about 10 to 40 mol % of carbon atoms and about 10 to 40 mol % of nitrogen atoms.

The tungsten carbon nitride pattern 106a has good reaction resistance to the dielectric layer 104 with a high dielectric constant and has a work function of about 4.9 eV to about 5.2 eV that is suitable for the gate electrode of the PMOS transistor.

A conductive layer pattern 112a may be further formed on the tungsten carbon nitride pattern 106a. The conductive layer pattern 112a patterns the gate electrode and defines a contact area on the substrate 100. The conductive layer pattern 112a may include a metal layer pattern or a metal silicide layer pattern. For example, the metal layer pattern includes tungsten, tantalum, titanium, aluminum, copper, etc., and the metal silicide layer pattern includes titanium silicide, cobalt silicide, tungsten silicide, tantalum silicide, etc. In addition, the conductive layer pattern 112a may include a doped polysilicon layer pattern.

In an example embodiment of the present invention, the conductive layer pattern 112a includes a doped polysilicon layer pattern 108a and a tungsten layer pattern 110a that are sequentially stacked on the tungsten carbon nitride pattern 106a.

FIGS. 2 to 5 are schematic cross-sectional views illustrating processing steps for a method of forming the gate structure shown in FIG. 1.

Referring to FIG. 2, an isolation layer 102 is formed at an upper portion of a substrate 100, so that an active region is defined by the isolation layer 102 on the substrate 100. Various conductive structures and devices on a first active region of a substrate are electrically isolated from those on an adjacent active region due to the isolation layer 102, so that the isolation layer 102 is referred to as a device isolation layer, hereinafter. In an example embodiment, the device isolation layer 102 may be formed on the substrate 100 by a shallow trench isolation (STI) process because the STI process is more favorable to a high integration degree of a semiconductor device. N-type impurities are implanted onto the active region of the substrate 100, so that a channel region (not shown) of a PMOS transistor is formed at a surface portion of the active region of the substrate 100.

A dielectric layer 104 having a high dielectric constant is formed on the substrate 100 including on the device isolation layer 102. The dielectric layer 104 functions as a gate oxide layer of a MOS transistor according to the present invention. In an example embodiment, the dielectric layer 102 includes an insulation material having a dielectric constant that is higher than that of silicon oxide (SiO₂).

The dielectric layer 104 may include a metal oxide. Examples of the metal oxides that may be included in layer 104 are tantalum oxide (Ta₂O₅), titanium oxide (TiO₂), hafnium oxide (HfO₂), zirconium oxide (ZrO₂), hafnium silicon oxide (HfSiₓO_{y}), zirconium silicon oxide (ZrSiₓO_{y}), hafnium silicon oxy nitride (HfSiₓO_{y}N_{z}), zirconium silicon oxy nitride (ZrSiₓO_{y}N_{z}), aluminum oxide (Al₂O₃), aluminum oxy nitride (AlₓO_{y}N_{z}), hafnium aluminum oxide (HfAlₓO_{y}), yttrium oxide (Y₂O₃), niobium oxide (Nb₂O₅), cerium oxide (CeO₂), indium oxide (InO₃), lanthanum oxide (LaO₂), iridium oxide (IrO₂), barium strontium titanium oxide ((Ba,Sr)TiO₃, also known as BST), lead zirconium titanium oxide (Pb(Zr,Ti)O₃, also known as PZT), strontium titanium oxide (SrTiO₃), lead titanium oxide (PbTiO₃), strontium ruthenium oxide (SrRuO₃), calcium ruthenium oxide (CaRuO₃), lead lanthanum zirconium titanium oxide ((Pb,La)(Zr,Ti)O₃), strontium calcium ruthenium oxide ((Sr,Ca)RuO₃), etc. In the preceding list, x, y and z are integers. These materials may be used alone or in a combination thereof. The dielectric layer 104 may be a single-layered structure or alternatively may be a multi-layered structure including a plurality of layers comprising one or more of the above example metal oxides.

The dielectric layer 104 may be formed by a deposition process such as a chemical vapor deposition (CVD) process, an atomic layer deposition (ALD) process or a metal-organic chemical vapor deposition (MOCVD) process. The high dielectric constant of the dielectric layer 104 is caused by a strong ionic polarization of the dielectric material. The dielectric layer 104 may be formed substantially free of impurities and have a chemically correct stoichiometry. In addition, the dielectric layer 104 may have a crystalline structure. In one illustrative invention embodiment, the dielectric layer 104 is formed through a metal organic CVD process and using a subsequent heat treatment. A metal oxide as listed above may be deposited onto the substrate 100 by a metal organic CVD process at a temperature of about 400° C. to about 700° C. A low temperature CVD process is favorable to improving a step coverage of a deposited layer, however, such a process is unfavorable to forming a deposited layer having a high dielectric constant. Thus, a heat treatment is further performed onto the deposited metal oxide layer, to thereby form the dielectric layer 104 having a suitably high dielectric constant on the substrate 100. As a result, the dielectric layer 104 formed in accordance with this invention has both an excellent step coverage as well as demonstrating improved capacitance and current leakage characteristics.

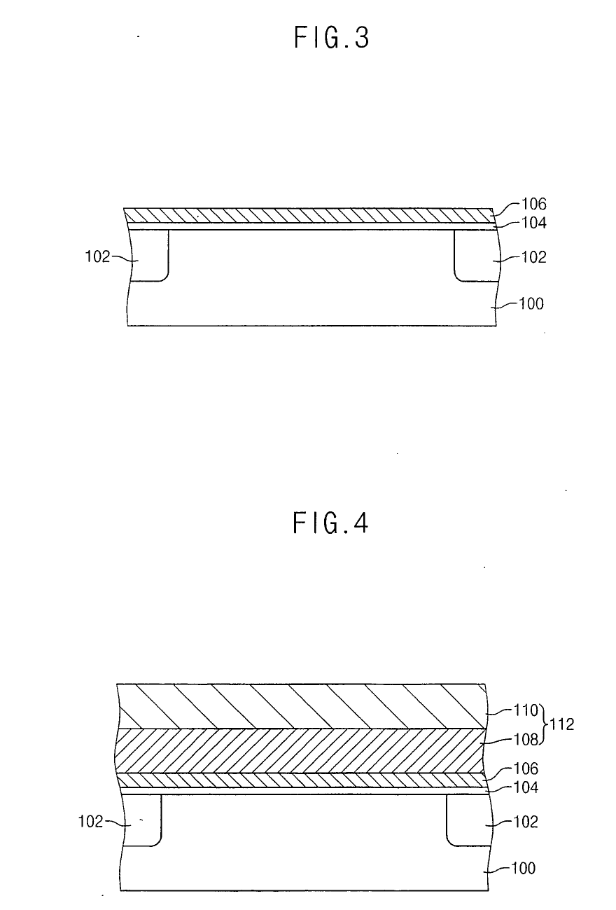

Referring now to FIG. 3, a tungsten carbon nitride layer 106 is formed on the dielectric layer 104. In an example embodiment, a source gas including a tungsten amine derivative is provided into a processing chamber (not shown) containing the substrate with layer 104. The tungsten amine derivative can be represented by the general chemical formula W(NR₁R₂)₂(NR₃)₂, wherein R₁, R₂ and R₃ denote hydrogen atoms or a C₁-C₆ alkyl group, and may be the same as or different from one another. The source gas, or at least the tungsten amine derivative component of the source gas, is decomposed by a thermal decomposition process in the processing chamber, with the result that a tungsten carbon nitride layer 106 is formed on the dielectric layer 104.

When a gate electrode making direct contact with the dielectric layer 104 comprises polysilicon, a Fermi-level pinning phenomenon can occur between the gate electrode and the dielectric layer 104, and a threshold voltage of a PMOS transistor is increased due to the Fermi-level pinning phenomenon. For the above reasons, the gate electrode of the PMOS transistor should preferably include a conductive material having a conductivity that is sufficient for minimizing the Fermi-level pinning phenomenon. The gate electrode of the PMOS transistor should also preferably have a sufficient oxidation resistance for suppressing an oxidation process that may cause an increase of an equivalent oxide thickness (EOT). Further, the gate electrode of the PMOS transistor should also preferably have a high work function of about 4.8 eV to about 5.2 eV. The tungsten carbon nitride layer 106 of the present embodiment sufficiently satisfies all of the above requirements or preferred characteristics of the gate electrode.

In a more specific embodiment, the tungsten carbon nitride layer 106 may be formed by a metal organic chemical vapor deposition (MOCVD) process using a source gas including a metal organic precursor as described hereinafter.

In an example embodiment, the source gas including the metal organic precursor includes bis(tert-butylimido)bis(dimetylamido)tungsten. Bis(tert-butylimido)bis(dimetylamido)tungsten can be represented by the following chemical formula.
[Chemical Formula]

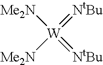

A carrier gas may be further provided into the chamber in order to supply the source gas into the chamber. The carrier gas is preferably a substantially inert gas such as argon, helium and/or nitrogen.

A pressure control gas may be further provided into the chamber to control an inner pressure of the chamber. The pressure control gas is also preferably a substantially inert gas such as argon, helium and/or nitrogen. The pressure control gas may flow into the chamber through a supply line different from that of the carrier gas. The pressure control gas may be the same as or different from the carrier gas.

A deposition pressure in the chamber may be maintained at about 0.1 to about 100 torr and a deposition temperature may be maintained at about 400 to about 700° C. to thermally decompose the source gas.

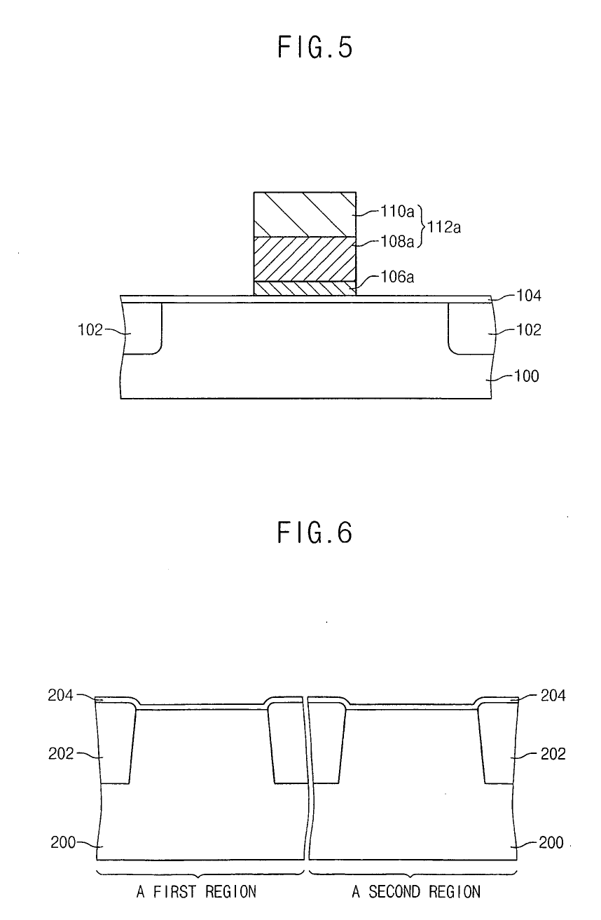

Since the tungsten carbon nitride layer 106 formed by the MOCVD process using bis(tert-butylimido)bis(dimetylamido)tungsten as the precursor has a work function of about 5 eV, the tungsten carbon nitride layer 106 is particularly suitable for the gate electrode in the PMOS transistor. In the tungsten carbon nitride pattern 106a (as seen in FIG. 5), about 10 mol % to about 40 mol % of carbon and about 10 mol % to about 40 mol % of nitrogen out of a total amount of the tungsten carbon nitride pattern 106a are included.

A reaction gas including nitrogen or a nitrogen-containing compound may be further provided into the chamber during the deposition to control a nitrogen content included in the tungsten carbon nitride layer 106. The reaction gas including nitrogen or a nitrogen-containing compound may include nitrogen (N₂), ammonia (NH₃), diazene (N₂H₂), etc.

A reaction gas including a carbon-containing compound may be further provided into the chamber during the deposition to control a carbon content included in the tungsten carbon nitride layer 106. The reaction gas including a carbon-containing compound may include methane (CH₄), etc.

The relative proportions of nitrogen and carbon may change the work function of the tungsten carbon nitride layer 106 that is formed in this step of the process.

A post-treatment may be performed after the tungsten carbon nitride layer 106 is formed. The post-treatment may be performed using a reactant activated by a remote plasma method or a direct plasma method. For example, the reactant that is plasma-activated includes ammonia (NH₃), hydrogen (H₂), nitrogen (N₂), silane (SiH₄), disilane (Si₂H₆), etc.

The tungsten carbon nitride layer 106 formed by the MOCVD process of this invention using the metal organic precursor and the carrier gas as described above shows less damage and has an improved step coverage compared with a tungsten carbon nitride layer formed by a physical vapor deposition (PVD) process. When a thin layer including tungsten is formed by a CVD process using tungsten hexafluoride (WF₆) or tungsten chloride (WCl) as a source gas, there is a problem that the thin layer including tungsten is relatively easily corroded by a reaction-by-product such as iron (Fe) or chlorine (Cl). The tungsten carbon nitride layer 106 formed by the MOCVD process of this invention using the metal organic precursor and the carrier gas may alleviate such corrosion problems in whole or at least in part.

Referring now to FIG. 4, a conductive layer 112 is formed on the tungsten carbon nitride layer 106, so that a contact through which an electrical signal is transferred to the gate electrode is easily formed in a subsequent process.

The conductive layer 112 may be formed by depositing a metal or a metal silicide onto the tungsten carbon nitride layer 106. Examples of the metal that may be used in this step include tungsten, tantalum, titanium, aluminum, copper, etc. Examples of the metal silicide that may be used in this step include titanium silicide, cobalt silicide, tungsten silicide, tantalum silicide, etc. These can be used alone or in a combination thereof. The conductive layer 112 may be a single-layered or a multi-layered structure including a plurality of the single layers. In an example embodiment of the present invention, the conductive layer 112 is formed as a multilayer structure including a polysilicon layer 108 and a tungsten layer 110 formed on the polysilicon layer 108.

Referring next to FIG. 5, a hard mask layer (not shown) is formed on the conductive layer 112 of FIG. 4, and a photolithography process and an etching process are performed on the hard mask layer, to thereby form a hard mask layer pattern (not shown) on the conductive layer 112.

A gate electrode structure, including a tungsten carbon nitride pattern 106a and a conductive layer pattern 112a, is formed on the dielectric layer 104 by sequentially patterning the conductive layer 112 of FIG. 4 and the tungsten carbon nitride layer 106 using the hard mask pattern as an etch mask.

A gate spacer (not shown) may be further formed on a sidewall of the gate electrode structure. A source/drain region is formed at surface portions of the substrate 100 by implanting P-type impurities onto the substrate 100 using the gate spacer and the gate electrode structure as a mask. After the ion implantation process is performed, a heat treatment may be further preformed on the substrate 100, to thereby activate the implanted impurities. The heat treatment process may include a rapid thermal process (RTP). After performing the above processes, the PMOS transistor is completed.

According to the above process, the gate structure including a gate electrode having the work function of about 5.0 eV, the gate electrode also preventing Fermi-level pinning phenomenon, is formed although the dielectric layer having the high dielectric constant is used as the gate oxide layer. Using such an improved gate structure, a semiconductor device having a high integration and a high efficiency may be manufactured.

### Embodiment 2

FIGS. 6 to 10 are schematic cross-sectional views illustrating a method of manufacturing a dual gate of a semiconductor device in accordance with a second embodiment of the present invention.

Referring to FIG. 6, a substrate 200 is prepared. The substrate 200 includes a first region to form an N-type transistor and a second region separated from the first region to form a P-type transistor. An active region and an isolation region are defined using an isolation layer 202 formed by a shallow trench isolation (STI) process on the substrate 200.

A first channel region (not shown) doped with a P-type impurity is formed in the active region of the first region, and a second channel region (not shown) doped with an N-type impurity is formed in the active region of the second region.

A dielectric layer 204 having a high dielectric constant as defined herein is formed by a deposition process using metal oxides on the substrate 200. The dielectric layer 204 is formed by substantially the same processes as those illustrated and described in the first embodiment of the present invention for forming dielectric layer 104.

When the high dielectric layer 204 and the substrate 200 are directly connected, a silicate layer may be formed by a reaction of the high dielectric layer 204 and the substrate 200 during a post-thermal process. In an example embodiment of the present invention, a thin silicate layer may be formed between the high dielectic layer 204 and the substrate 200 before completing the step of forming the high dielectric layer 204 to minimize a formation of such a silicate layer. For example, a hafnium silicate layer is formed as a silicate layer before a hafnium oxide layer is formed. As a result, the high dielectric layer 204 having a relatively thin silicate layer may be formed.

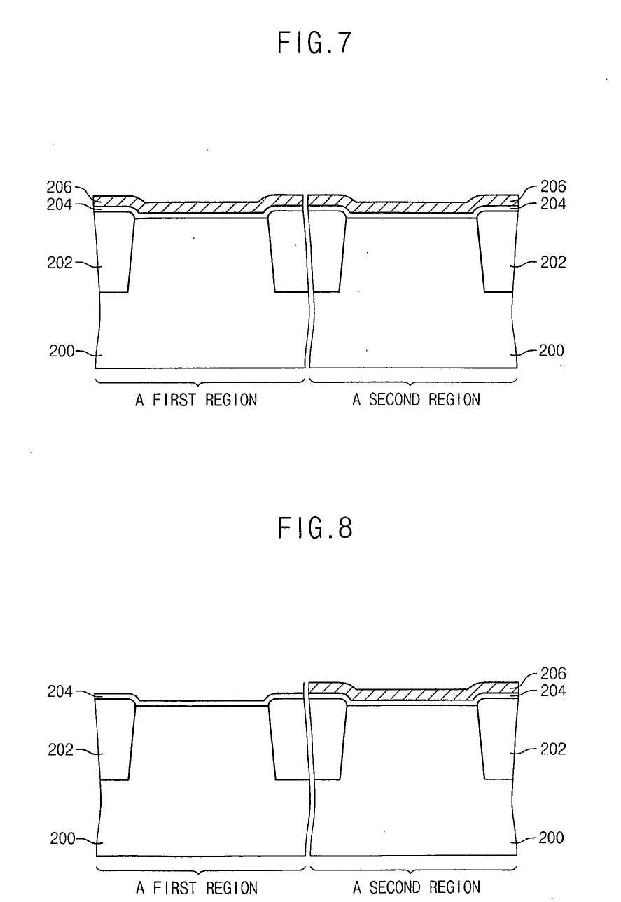

Referring to FIG. 7, a source gas including a tungsten amine derivative is provided onto the high dielectric layer 204. The source gas may include W(NR₁R₂)₂(NR₃)₂. In the formula, R₁, R₂ and R₃ are hydrogen atoms or a C₁-C₆ alkyl group. The tungsten carbon nitride layer 206 is formed on the dielectric layer 204 by thermally decomposing at least the tungsten amine derivative component of the source gas. The tungsten carbon nitride layer 206 is formed by substantially the same processes as those illustrated and described in the first embodiment of the present invention for forming layer 106. In an example embodiment of the present invention, the tungsten carbon nitride layer 206 may be thinly formed to easily control an etching process in a subsequent process wherein the tungsten carbon nitride layer 206 is partially removed. Thus, the tungsten carbon nitride layer 206 may be formed as thin as possible consistent with obtaining a work function of the gate electrode as required in a PMOS transistor. The tungsten carbon nitride layer 206 may, for example, have a thickness of about 30 Å to about 1000 Å. More preferably, the tungsten carbon nitride layer 206 may have a thickness of about 30 Å to about 100 Å.

Referring now to FIG. 8, a photoresist is spin-coated on the tungsten carbon nitride layer 206. Thereafter, a photoresist pattern (not shown) is formed by an exposure and a development process. The exposure and the development processes expose the tungsten carbon nitride layer 206 positioned on the first region to form the photoresist pattern.

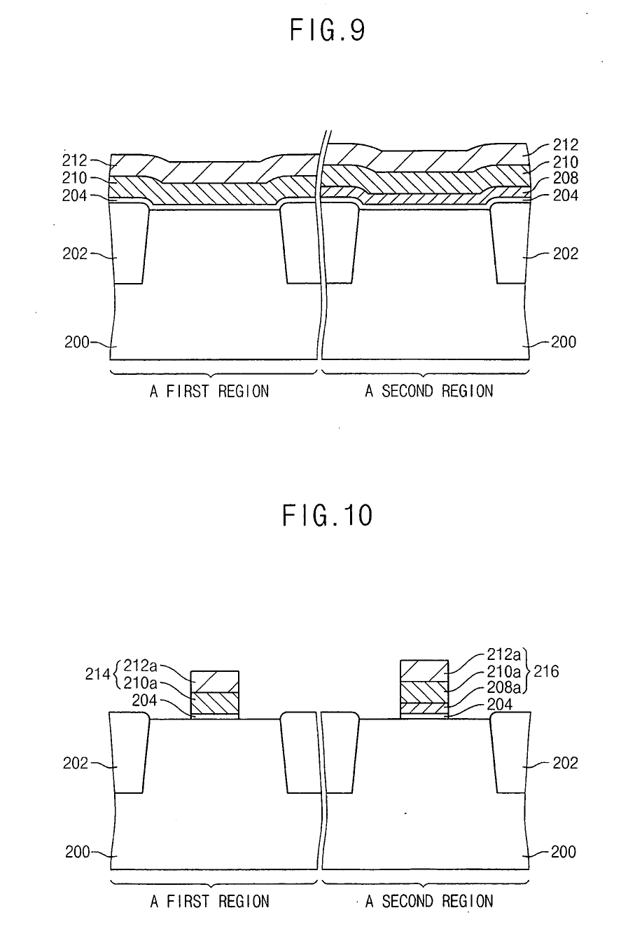

A preliminary tungsten carbon nitride layer pattern 208 (as seen in FIG. 9) is formed using the photoresist pattern as an etch mask by partially removing the tungsten carbon nitride layer 206 positioned on the first region. The preliminary tungsten carbon nitride layer pattern 208 is provided as a gate electrode of the PMOS transistor.

Thereafter, the photoresist pattern is removed by an ashing process and a strip processes. When the tungsten carbon nitride layer 206 is removed using plasma by a dry etching process, the dielectric layer 204 under the tungsten carbon nitride layer 206 may be damaged by plasma so that the electrical properties of an NMOS transistor may be deteriorated. Thus, the partial removal of the tungsten carbon nitride layer 206 may instead be performed by a wet etching process. Since the tungsten carbon nitride layer 206 is easily removed using a wet etchant, the dielectric layer 204 under the tungsten carbon nitride layer 206 may avoid damages. In addition, a remaining portion of tungsten carbon nitride layer 206 in the first region process may be decreased when the wet etch process is performed compared with the results of using the dry etching process.

Referring next to FIG. 9, a first conductive layer 210 is formed on the preliminary tungsten carbon nitride layer pattern 208 in the second region and on the dielectric layer 204 in the first region. The first conductive layer 210 has a work function lower than that of the preliminary tungsten carbon nitride pattern 208. The first conductive layer 210 applied to the gate electrode of the NMOS transistor may include a conductive material having a work function of about 3.8 eV to about 4.2 eV. In one embodiment, the first conductive layer 210 may be formed using polysilicon doped with an N-type impurity. In an alternative embodiment, the first conductive layer 210 may be formed using a metal compound or a metal having a work function of about 3.8 eV to 4.2 eV.

When a polysilicon layer doped with an N-type impurity is formed on the dielectric layer 204, an increase in a threshold voltage caused by a Fermi-level pinning phenomenon is smaller than that in the case of a polysilicon layer doped with a P-type impurity. Thus, the NMOS transistor having a threshold voltage of about 0.3 to about 0.9 V may be formed with a polysilicon layer doped with a N-type impurity through a channel doping process. In an example embodiment of present invention, the polysilicon layer with the N-type impurity is formed as the first conductive layer 210.

In addition, a second conductive layer 212 may be formed on the first conductive layer 210 to reduce a resistivity of a whole gate structure. The second conductive layer 212 may include a metal such as tungsten, tantalum, titanium, aluminum and copper, or a metal silicide such as titanium silicide, cobalt silicide, tungsten silicide and tantalum silicide.

Referring next to FIG. 10, a hard mask layer (not shown) including silicon nitride is formed on the second conductive layer 212 (as seen in FIG. 9). Thereafter, the hard mask pattern is formed to pattern a gate structure in the first region and the second region by performing a photolithography process and an etching process.

A first gate electrode structure 214 and a second gate electrode structure 216 are respectively formed in the first region and the second region using the hard mask pattern as an etch mask by sequentially etching the second conductive layer, the first conductive layer and the preliminary tungsten carbon nitride layer pattern 208. The first gate electrode structure 214 includes a first conductive layer pattern 210a and a second conductive layer pattern 212a. The second gate electrode structure 216 includes a tungsten carbon nitride layer pattern 208a, a first conductive layer pattern 210a and the second conductive layer pattern 212a.

According to the above processes, a gate electrode substantially determining the threshold voltage of the NMOS transistor may include the first conductive layer pattern 210a having a work function of about 3.8 eV to 4.2 eV, and a gate electrode substantially determining the threshold voltage of the PMOS transistor may include the tungsten carbon nitride layer pattern 208a having a work function of about 4.9 eV to 5.2 eV.

According to the above processes, the dual gate electrode is completed. The dual gate electrode prepared in accordance with this invention may have the threshold voltage required by semiconductor memory devices even though the dual gate electrode uses a dielectric layer having a high dielectric constant as the gate oxide layer. More particularly, when the tungsten carbon nitride layer is formed on the dielectric layer in a PMOS transistor, a familiar prior art problem of depleting a polysilicon layer is avoided.

In an example embodiment of the present invention, spacers may be formed on sidewalls of the first gate electrode structure 214 and also on the second gate electrode structures 216. An NMOS source/drain region is formed at an upper portion of the substrate adjacent to the first gate electrode structure 214 by injecting an N-type impurity into the substrate adjacent to the first gate electrode structure 214. In addition, a PMOS source/drain region is formed at an upper potion of the substrate adjacent to the second gate electrode structure 216 by injecting a P-type impurity into the substrate next to the second gate electrode structure 216. As a result, a CMOS transistor is completed.

### Embodiment 3

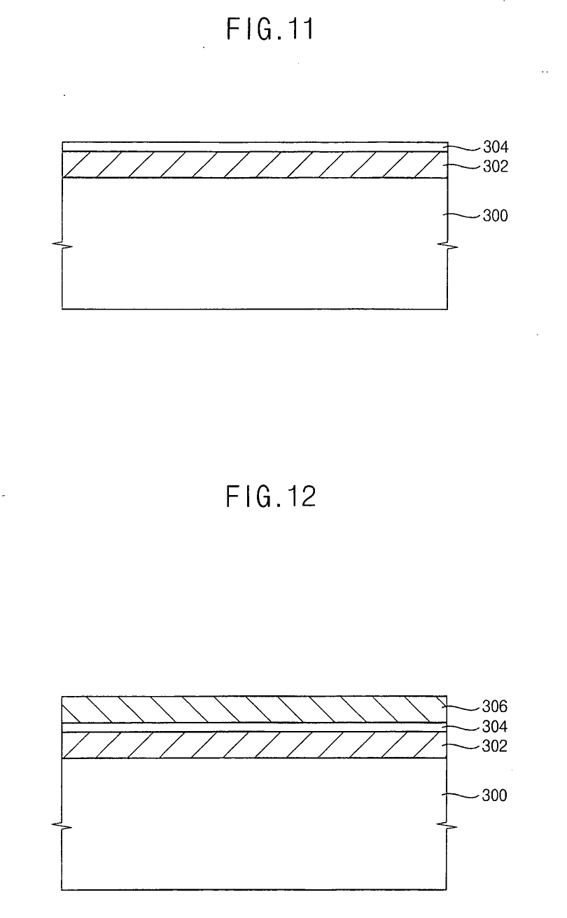

FIGS. 11 and 12 are schematic cross-sectional views illustrating a method of manufacturing a capacitor in accordance with a third embodiment of the present invention.

Referring to FIG. 11, a source gas including a tungsten amine derivative is provided onto a substrate 300. The source gas may include W(NR₁R₂)₂(NR₃)₂. In the preceding formula, R₁, R₂ and R₃ are hydrogen atoms or a C₁-C₆ alkyl group. Thereafter, a tungsten carbon nitride layer as a first electrode layer 302 is formed on the substrate 300 by thermally decomposing at least the tungsten amine derivative component of the source gas. A method of forming the first electrode layer 302 is substantially the same as that of forming the tungsten carbon nitride layer illustrated and described in the first embodiment of the present invention for forming layer 106.

A dielectric layer 304 having a high dielectric constant as defined herein is formed on the first electrode layer 302. The dielectric layer 304 may include one or more metal oxides. For example, the dielectric layer 304 includes tantalum oxide (Ta₂O₅), titanium oxide (TiO₂), hafnium oxide (HfO₂), zirconium oxide (ZrO₂), hafnium silicon oxide (HfSiₓO_{y}), zirconium silicon oxide (ZrSiₓO_{y}), hafnium silicon oxy nitride (HfSiₓO_{y}N_{z}), zirconium silicon oxy nitride (ZrSiₓO_{y}N_{z}), aluminum oxide (Al₂O₃), aluminum oxy nitride (AlₓO_{y}N_{z}), hafnium aluminum oxide (HfAlₓO_{y}), yttrium oxide (Y₂O₃), niobium oxide (Nb₂O₅), cerium oxide (CeO₂), indium oxide (InO₃), lanthanum oxide (LaO₂), iridium oxide (IrO₂), barium strontium titanium oxide ((Ba,Sr)TiO₃, also known as BST), lead zirconium titanium oxide (Pb(Zr,Ti)O₃, also known as PZT), strontium titanium oxide (SrTiO₃), lead titanium oxide (PbTiO₃), strontium ruthenium oxide (SrRuO₃), calcium ruthenium oxide (CaRuO₃), lead lanthanum zirconium titanium oxide ((Pb,La)(Zr,Ti)O₃), strontium calcium ruthenium oxide ((Sr,Ca)RuO₃), etc. In the preceding list, x, y and z are integers. These materials may be used alone or in a combination thereof. The dielectric layer 304 may be a single-layered structure or alternatively may be a multi-layered structure including a plurality of layers comprising one or more of the above example metal oxides.

Referring to FIG. 12, a second electrode layer 306 is formed on the dielectric layer 304. The second electrode layer 306 may be or include a ruthenium layer, a platinum layer, an iridium layer, a titanium nitride layer, a tantalum nitride layer, a tungsten carbon nitride layer, a tantalum carbon nitride layer, etc.

When the second electrode layer 306 includes a tungsten carbon nitride layer, the second electrode layer may be formed by substantially the same method as that of the first electrode layer 302. In an example embodiment of the present invention (not shown in FIG. 12), a capping layer including tantalum nitrides may be formed on the second electrode 306.

Therefore, the capacitor including the first electrode layer 302, the dielectric layer 304 and the second electrode layer 306 are completed. The first electrode layer 302 may correspond to a lower electrode, and the second electrode layer 306 may correspond to an upper electrode.

In an example embodiment of the present invention, a metal oxide having a high dielectric constant as defined herein may be used as a dielectric layer by forming the first electrode and/or the second electrode with tungsten carbon nitride. As a result, a capacitor having a relatively higher capacitance may be formed. The leakage current of the capacitor may be minimized by forming the first electrode and the second electrode using metal compounds that exhibit high work functions. The method of forming the capacitor in accordance with this invention embodiment may be applied, for example, to fabricate a device such as a dynamic random access memory (DRAM) device.

Hereinafter, experimental results analyzing a characteristic of the tungsten carbon nitride layer and a semiconductor device having such a tungsten carbon nitride layer will be described.

Characteristic Analysis of a Tungsten Carbon Nitride Layer

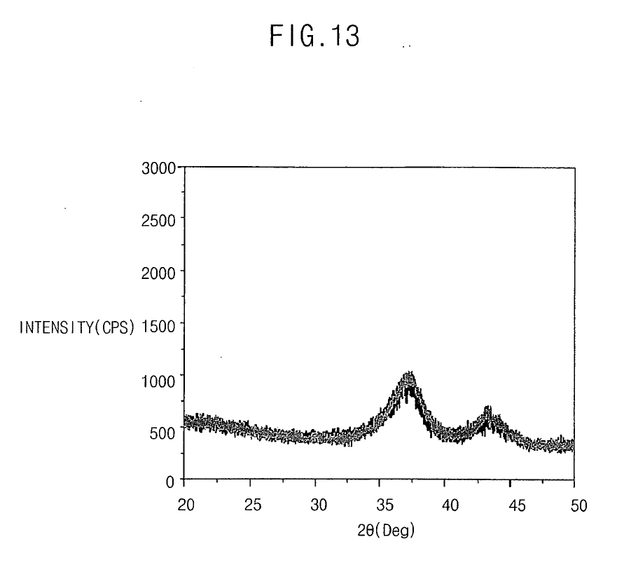

FIG. 13 is a graph illustrating characteristics of x-ray diffraction patterns in a tungsten carbon nitride layer of a semiconductor device formed according to the present invention.

For the purposes of this experimental testing, a silicon oxide layer having a thickness of about 1000 Å was first formed on a bare silicon substrate, and sequentially thereafter the tungsten carbon nitride layer was formed according to the example embodiments of the present invention. The source gas for forming the tungsten carbon nitride layer included a metal organic precursor of bis(tert-butylimido)bis(dimetylamido)tungsten.

Based on interpreting the data illustrated in FIG. 13, the tungsten carbon nitride layer exists as crystalline W₂N phases. When an atomic composition of the tungsten carbon nitride layer was analyzed by Rutherford Backscattering Spectroscopy (RBS), nitrogen in the tungsten carbon nitride layer had a concentration of about 10 mol % to 40 mol % and carbon had a concentration of about 10 mol % to 40 mol % in accordance with a deposition condition.

### Comparative Example Embodiments

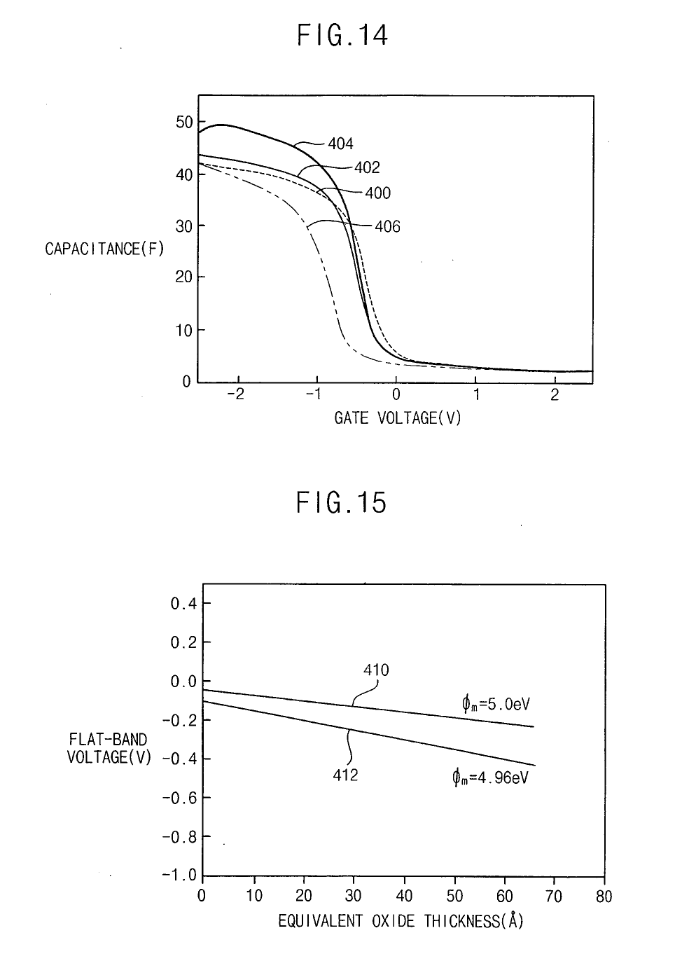

FIG. 14 is a graph illustrating capacitance-voltage (C-V) characteristics of a MOS capacitor having a tungsten carbon nitride layer of the present invention, and various electrode materials as a gate electrode.

The MOS capacitor according to an example embodiment of the present invention includes a hafnium silicon oxy nitride layer and the tungsten carbon nitride layer sequentially formed on a silicon substrate.

The MOS capacitor used as a first comparative sample includes the hafnium silicon oxy nitride layer and a tantalum carbon nitride layer sequentially formed on a silicon substrate by a CVD method.

The MOS capacitor used as a second comparative sample includes the hafnium silicon oxy nitride layer and a tungsten nitride layer sequentially formed on a silicon substrate by a PVD method.

The MOS capacitor used as a third comparative sample includes the hafnium silicon oxy nitride layer and a polysilicon layer doped with an N-type impurity sequentially on a silicon substrate.

In FIG. 14, a reference numeral 400 indicates a C-V characteristic curve for the MOS capacitor according to the present invention. A reference numeral 402 indicates a C-V characteristic curve for the MOS capacitor of the first comparative sample. A reference numeral 404 indicates a C-V characteristic curve for the MOS capacitor of the second comparative sample. A reference numeral 406 indicates a C-V characteristic curve for the MOS capacitor of the third comparative sample.

Referring to FIG. 14, it can be seen that the C-V curve 400 of the MOS capacitor according to the present invention is shifted to the right by about 500 mV compared with the C-V curve 406 of the comparative MOS capacitor doped with an N-type impurity. The shift of the C-V curve 400 in FIG. 14 indicates that using a tungsten carbon nitride layer in accordance with this invention may provide an adequate work function applicable to a gate electrode of a PMOS transistor. An accumulation capacitance in the MOS capacitor of the present invention is an equivalent level with that in the MOS capacitor using the tantalum carbon nitride layer and the polysilicion doped with an N-type impurity. In addition, FIG. 14 shows that an accumulation capacitance in the MOS capacitor of the present invention (represented by curve 400) is at a level lower than that in the comparative MOS capacitor using the tungsten nitride layer formed by a PVD process (represented by curve 404), whereas an accumulation capacitance in the MOS capacitor of the present invention is at a level substantially equivalent to that in the MOS capacitor using the tantalum carbon nitride layer and the polysilicon doped with an N-type impurity (represented by curve 406). Therefore, a tungsten carbon nitride layer in accordance with this invention may provide thermal and chemical stability with respect to a dielectric layer having a high dielectric constant as a gate oxide layer.

FIG. 15 is a graph illustrating the variation in flat-band voltage and a work function of a tungsten carbon nitride layer according to a thickness of a hafnium silicon oxy nitride layer.

In FIG. 15, a reference numeral 410 indicates a flat-band voltage curve for the tungsten carbon nitride layer formed by an MOCVD process at a temperature of 600° C. according to an equivalent oxidation layer thickness, and a reference numeral 420 indicates a flat-band voltage curve for the tungsten carbon nitride layer formed by an MOCVD process at a temperature of 550° C. according to an equivalent oxidation layer thickness.

Referring to FIG. 15, the tungsten carbon nitride layer formed by the MOCVD process at the temperature of 600° C. (line 410) has a work function of 5.0 eV, and the tungsten carbon nitride formed by the MOCVD process at the temperature of 550° C. (line 412) has a work function of 4.96 eV. As previously discussed, a tungsten carbon nitride layer having a work function of about 5.0 eV is suitable for being applied to the gate electrode of the PMOS transistor.

According to the present invention, a gate electrode having good reaction resistance to a dielectric layer having a high dielectric constant and a gate electrode having an adequate work function applicable to the PMOS transistor may be formed by the methods herein described. In addition, a capacitor electrode layer capable of reducing a leakage current with a dielectric layer having a high dielectric constant may be formed. Therefore, the efficiency of a semiconductor device may be improved by applying the methods of this invention to the fabrication process.

The foregoing description is illustrative of the present invention and is not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

What is claimed is:

1. A method of manufacturing a gate electrode structure, comprising the following sequential steps:
forming a dielectric layer having a high dielectric constant on a semiconductor substrate;
providing a source gas including a tungsten amine derivative onto the dielectric layer;
forming a tungsten carbon nitride layer on the dielectric layer by a thermal decomposition of the source gas; and
forming a gate electrode by patterning the tungsten carbon nitride layer.

2. The method of claim 1, wherein the tungsten amine derivative is represented by a chemical formula of W(NR₁R₂)₂(NR₃)₂, wherein R₁, R₂ and R₃ are independently selected from the group consisting of hydrogen atoms and C₁-C₆ alkyl groups.

3. The method of claim 1, wherein the tungsten amine derivative comprises bis(tert-butylimido)bis(dimetylamido)tungsten.

4. The method of claim 1, wherein the dielectric layer comprises at least one member selected from the group consisting of tantalum oxide (Ta₂O₅), titanium oxide (TiO₂), hafnium oxide (HfO₂), zirconium oxide (ZrO₂), hafnium silicon oxide (HfSiₓO_{y}), zirconium silicon oxide (ZrSiₓO_{y}), hafnium silicon oxy nitride (HfSiₓO_{y}N_{z}), zirconium silicon oxy nitride (ZrSiₓO_{y}N_{z}), aluminum oxide (Al₂O₃), aluminum oxy nitride (AlₓO_{y}N_{z}), hafnium aluminum oxide (HfAlₓO_{y}), yttrium oxide (Y₂O₃), niobium oxide (Nb₂O₅), cerium oxide (CeO₂), indium oxide (InO₃), lanthanum oxide (LaO₂), iridium oxide (IrO₂), barium strontium titanium oxide ((Ba,Sr)TiO₃, BST), lead zirconium titanium oxide (Pb(Zr,Ti)O₃, PZT), strontium titanium oxide (SrTiO₃), lead titanium oxide (PbTiO₃), strontium ruthenium oxide (SrRuO₃), calcium ruthenium oxide (CaRuO₃), lead lanthanum zirconium titanium oxide ((Pb,La)(Zr,Ti)O₃) and strontium calcium ruthenium oxide ((Sr,Ca)RuO₃) wherein x, y and z are integers.

5. The method of claim 1, further comprising the step of providing a carrier gas and the step of providing a pressure control gas onto the substrate, wherein the carrier gas carries a precursor onto the substrate and the pressure control gas controls a pressure in a reaction chamber containing the substrate.

6. The method of claim 5, wherein the carrier gas is selected from the group consisting of argon, helium and nitrogen and mixtures thereof.

7. The method of claim 5, wherein the pressure control gas is selected from the group consisting of argon, helium and nitrogen and mixtures thereof.

8. The method of claim 1, wherein the thermal decomposition of the source gas is performed at a temperature of about 400 to 700° C. and at a pressure of about 0.1 to 100 torr.

9. The method of claim 1, further comprising the step of providing a reaction gas including nitrogen onto a substrate to control a nitrogen content in the tungsten carbon nitride layer.

10. The method of claim 1, further comprising the step of providing a reaction gas including carbon onto a substrate to control a carbon content in the tungsten carbon nitride layer.

11. The method of claim 1, further comprising a post-treatment step after a formation of the tungsten carbon nitride layer, said post-treatment step comprising performing a post-treatment using a reactant including at least one member selected from the group consisting of NH₃, H₂, N₂, SiH₄ and Si₂H₆, wherein said member is activated by a remote plasma method or a direct plasma method.

12. The method of claim 1, further comprising the step of forming a conductive layer on the tungsten carbon nitride layer.

13. A method of manufacturing a dual gate electrode, comprising the following sequential steps:
forming a dielectric layer having a high dielectric constant on a semiconductor substrate that includes an NMOS transistor region and a PMOS transistor region;
providing a source gas including a tungsten amine derivative onto the dielectric layer;
forming a tungsten carbon nitride layer having a first work function on the dielectric layer by decomposing the source gas, wherein the tungsten carbon nitride layer serves as a gate electrode for a PMOS transistor;
forming a preliminary tungsten carbon nitride layer pattern by partially etching the tungsten carbon nitride layer positioned in the NMOS transistor region;
forming a conductive layer having a second work function on the preliminary tungsten carbon nitride layer pattern and on the high dielectric layer pattern, wherein the conductive layer serves as a gate electrode for a NMOS transistor;
forming a first gate electrode on the dielectric layer of the PMOS transistor region by patterning the conductive layer and the tungsten carbon nitride layer, the first gate electrode including a tungsten carbon nitride layer pattern and a conductive layer pattern; and
forming a second gate electrode on the dielectric layer of the NMOS transistor region by patterning the conductive layer, wherein the second gate electrode includes a conductive layer pattern.

14. The method of claim 13, wherein the tungsten amine derivative is represented by the chemical formula W(NR₁R₂)₂(NR₃)₂, wherein R₁, R₂ and R₃ are independently selected from the group consisting of hydrogen atoms and C₁-C₆ alkyl groups.

15. The method of claim 14, wherein the tungsten amine derivative comprises bis(tert-butylimido)bis(dimetylamido)tungsten.

16. The method of claim 13, wherein the step of forming a preliminary tungsten carbon nitirdie pattern by partially etching the tungsten carbon nitride layer comprising the substeps of:
forming a photoresist pattern on the NMOS transistor region, so that the tungsten carbon nitride layer is partially exposed through the photoresist pattern; and
etching the tungsten carbon nitride layer by a wet etch process using the photoresist pattern as an etch mask, thereby forming the preliminary tungsten carbon nitride pattern.

17. The method of claim 13, wherein the conductive layer comprises a member selected from the group consisting of a metal, a metal compound and a doped semiconductor material having a work function of about 3.8 eV to 4.2 eV.

18. A method of manufacturing a capacitor comprising the following sequential steps:
providing a source gas including a tungsten amine derivative onto a semiconductor substrate;
forming a first electrode layer including tungsten carbon nitride on the substrate by decomposing the source gas;
forming a metal oxide layer including a dielectric material with a high dielectric constant on the first electrode layer; and
forming a second electrode layer on the metal oxide layer.

19. The method of claim 18, wherein the tungsten amine derivative is represented by the chemical formula W(NR₁R₂)₂(NR₃)₂, wherein R₁, R₂ and R₃ are independently selected from the group consisting of hydrogen atoms and C₁-C₆ alkyl groups.

20. The method of claim 19, wherein the tungsten amine derivative comprises bis(tert-butylimido)bis(dimetylamido)tungsten.

21. The method of claim 18, wherein the second electrode layer comprises tungsten carbon nitride formed by decomposing the source gas provided to the metal oxide layer.

22. The method of claim 18, wherein the second electrode layer comprises at least one member selected from the group consisting of polysilicon doped with an impurity, ruthenium, platinum, iridium, titanium nitride, tantalum nitride and tungsten nitride.
